(19) United States
(12) Patent Application Publication
(10) Pub. No.: US 2009/0127613 A1
(43) Pub. Date: May 21, 2009

(54) NONVOLATILE SEMICONDUCTOR MEMORY DEVICE AND METHOD OF MANUFACTURING THE SAME

(75) Inventor: Tamio Ikehashi, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/274,750

(22) Filed: Nov. 20, 2008

(30) Foreign Application Priority Data
Nov. 20, 2007 (JP) 2007-300776

(51) Int. Cl. H01L 29/788; H01L 29/68; H01L 21/04; G11C 11/34

(52) U.S. Cl. 257/316; 438/257; 257/E21.04; 365/185.01; 257/E29.17; 257/E29.3

(57) ABSTRACT

A nonvolatile semiconductor memory device comprises a memory cell array of plural memory cells arranged in matrix. Each memory cell includes a first gate insulator layer formed on a semiconductor substrate, a floating gate formed on the semiconductor substrate with the first gate insulator layer interposed therebetween, a second gate insulator layer formed on the floating gate, and a control gate formed on the floating gate with the second gate insulator layer interposed therebetween. The first gate insulator layer is a first cavity layer.

### CROSS-REFERENCE TO RELATED APPLICATION

This application is based upon and claims the benefit of priority from the prior Japanese Patent Application No. 2007-300776, filed on Nov. 20, 2007, the entire contents of which are incorporated herein by reference.

### BACKGROUND OF THE INVENTION

An electrically erasable programmable flash memory is known as a nonvolatile semiconductor memory. The flash memory comprises memory cells each usually including a MOS transistor of the stacked gate structure, which includes a floating gate serving as a charge storage layer and a control gate stacked thereon. A tunnel oxide is formed between the floating gate and the semiconductor substrate.

In the flash memory using such the memory cells, at the time of data write, the semiconductor substrate is grounded and a write voltage is applied to the control gate. As a result, a tunnel current flows via the tunnel oxide between the semiconductor substrate and the floating gate to store electrons in the floating gate. Thus, the memory cell is brought into a written state with a higher threshold. On the other hand, at the time of data erase, the control gate is grounded and the voltage on the silicon substrate is elevated up to an erase voltage. Thus, electrons in the floating gate are drawn therefrom to the semiconductor substrate. As a result, the memory cell is brought into an erased state with a lower threshold.

In the flash memory of the above-described memory cell structure, however, the tunnel oxide accumulates charge traps at every data rewrite and limits the number of rewrite operations to around 10⁵ as a problem. (“Simulation for Degradation of Flash Memory due to Charge Traps in the Tunnel Oxide”, Yokozawa et. al, Technical Report of the Institute of Electronics, Information and Communication Engineers, vol. 96, No. 63(19960523), pp. 17-24).

### SUMMARY OF THE INVENTION

In an aspect the present invention provides a nonvolatile semiconductor memory device, comprising a memory cell array of plural memory cells arranged in matrix, each memory cell including a first gate insulator layer formed on a semiconductor substrate, a floating gate formed on the semiconductor substrate with the first gate insulator layer interposed therebetween, a second gate insulator layer formed on the floating gate, and a control gate formed on the floating gate with the second gate insulator layer interposed therebetween, wherein the first gate insulator layer is a first cavity layer.

In another aspect the present invention provides a method of manufacturing nonvolatile semiconductor memory devices, comprising: forming a first gate insulator layer on a semiconductor substrate; forming a first gate layer turned into a floating gate on the first gate insulator layer; selectively removing the first gate layer and the first gate insulator layer to form a plurality of first isolation trenches extending in parallel with a first direction in the surface layer of the semiconductor substrate; forming a first support film to couple the side of the first isolation trench with the side of the first gate layer facing the first isolation trench, the first support film having a resistance to a first etchant; forming a second gate insulator layer on the first gate layer; forming a second gate layer turned into a control gate on the second gate insulator layer; forming a plurality of second isolation trenches extending in parallel with a second direction crossing the first direction, the second isolation trenches reaching from the second gate layer to the surface of the semiconductor substrate; and forming a first cavity layer between the semiconductor substrate and the first gate layer using the first etchant to remove the first gate insulator layer while leaving the first support film.

In yet another aspect the present invention provides a method of manufacturing nonvolatile semiconductor memory devices, comprising: forming a first gate insulator layer on a semiconductor substrate; forming a first gate layer turned into a floating gate on the first gate insulator layer; selectively removing the first gate layer and the first gate insulator layer to form a plurality of first isolation trenches extending in parallel with a first direction in the surface layer of the semiconductor substrate; forming a first support film to couple the side of the first isolation trench with the side of the first gate layer facing the first isolation trench, the first support film having a resistance to a first etchant; forming a second gate insulator layer on the first gate layer; forming a second gate layer turned into a control gate on the second gate insulator layer; forming a plurality of second isolation trenches extending in parallel with a second direction crossing the first direction, the second isolation trenches reaching from the second gate layer to the surface of the semiconductor substrate; forming a second support film to couple the side of the first gate layer with the side of the second gate layer, the sides forming the second isolation trench, the second support film having a resistance to the first etchant; and forming the first cavity layer between the semiconductor substrate and the first gate layer and forming the second cavity layer between the first gate layer and the second gate layer using the first etchant to remove the first and second gate insulator layers while leaving the first and second support films.

### BRIEF DESCRIPTION OF THE DRAWINGS

FIG. 1 is a plan view of a cell region in a NAND-type EEPROM according to a first embodiment.

FIGS. 2A and 2B are cross-sectional views taken along I-I′ line and II-II′ line in FIG. 1.

FIGS. 3A-12B are cross-sectional views showing the NAND-type EEPROM in order of process step.

FIG. 13 is a perspective view showing the NAND-type EEPROM in order of process step.

FIGS. 14A-21B are cross-sectional views showing a NAND-type EEPROM according to a second embodiment in order of process step.

FIG. 22 is a perspective view showing the NAND-type EEPROM in order of process step.

FIGS. 23A and 23B are cross-sectional views showing the NAND-type EEPROM in order of process step.

FIG. 24 is a cross-sectional view showing a NAND-type EEPROM according to a third embodiment.

FIGS. 25A and 25B are cross-sectional views showing a NAND-type EEPROM according to a fourth embodiment.

### DETAILED DESCRIPTION OF THE EMBODIMENTS

The embodiments of the invention will now be described with reference to the drawings.

### Structure in First Embodiment

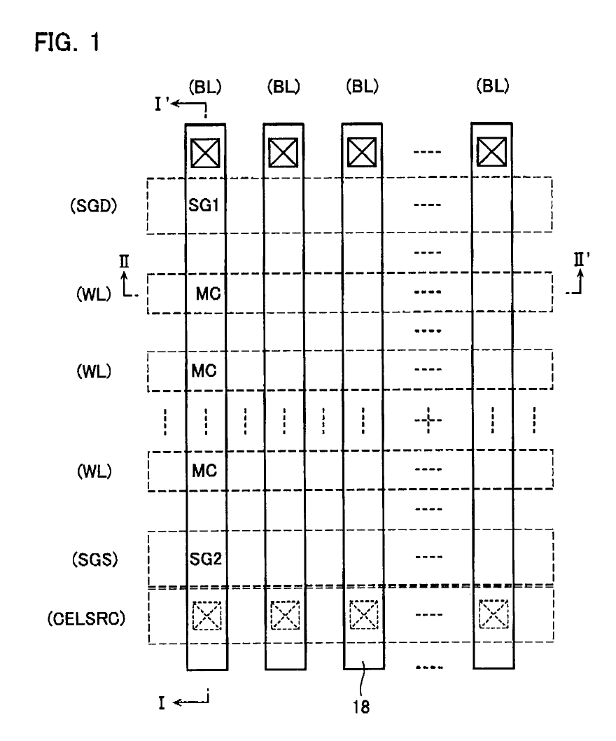

FIG. 1 is a plan view of a cell region in a NAND-type EEPROM (nonvolatile semiconductor memory device) according to a first embodiment of the present invention.

The cell region includes a plurality of bit lines BL formed therein, which extend in the longitudinal direction in the figure. A layer below these bit lines BL includes selection gates SGD, SGS and a common source line CELSRC formed therein, which extend in the lateral direction perpendicular to the bit line BL. It also includes a plurality of word lines WL, which are sandwiched between the selection gates SGD, SGS and extend in parallel with the selection gates SGD, SGS.

Memory cells MC are formed below intersections of the word lines WL and the bit lines BL. Selection gate transistors SG1, SG2 are formed below intersections of the selection gates SGD, SGS and the bit lines BL.

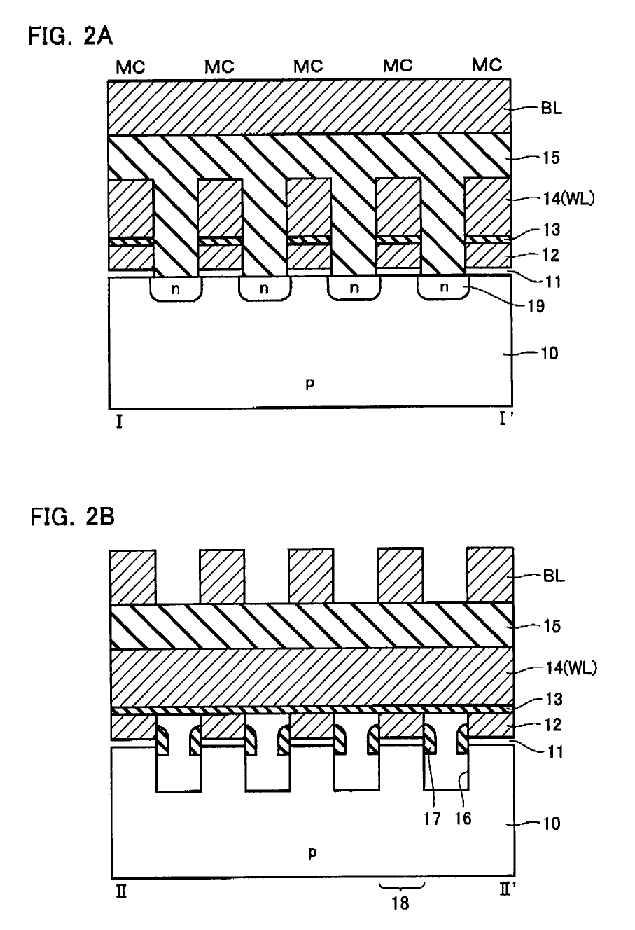

FIG. 2A is a cross-sectional view in a first direction or a row direction taken along the bit line BL (cross-sectional view taken I-I′ line in FIG. 1) in the NAND-type EEPROM according to the present embodiment. FIG. 2B is a cross-sectional view in a second direction or a column direction taken along the word line WL (cross-sectional view taken II-II′ line in FIG. 1).

As shown in FIGS. 2A, 2B, there is provided a p-type silicon substrate 10, for example, on which a first gate insulator layer or a first cavity layer 11, a floating gate 12 composed of polysilicon, a second gate insulator layer or an intergate insulator 13, and a control gate 14 composed of polysilicon are stacked in this turn to configure a memory cell MC together with the silicon substrate 10. The first cavity layer 11 may be kept in a vacuum or filled with a gas. In the case of filling a gas, an inert gas such as an N₂ gas and an Ar gas may be filled.

The floating gates 12 are separated from each other on a memory cell MC basis. The control gates 14 are formed continuously in a direction orthogonal to the bit line BL as the word lines WL or the selection gates SGD, SGS common to the memory cells MC arrayed in the direction orthogonal to the bit line BL or the selection gate transistors SG1, SG2. Although not shown, as for the selection gate transistors SG1, SG2, the floating gate 12 and the control gates 14 are short-circuited to configure a normal transistor.

In regions between the bit lines BL in the upper layer of the silicon substrate 10, isolation trenches 16 extending in the row direction are formed self-aligned with the floating gates 12, thereby defining stripe-shaped device regions 18, which are separated from each other in the column direction. In the isolation trenches 16, a first support film 17 composed of an insulator is formed to couple the upper portion of the side of the isolation trench 16 with the side of the floating gate 12 to keep the first cavity layer 11 with a certain thickness.

In portions of the upper layer of the device region 18 opposing the floating gate 12 via the first cavity layer 11, channel regions of the memory cells MC are formed. In addition, between these channel regions, n-type impurity-diffused regions 19 serving as a drain and a source shared by adjoining memory cells MC are formed.

The first cavity layer 11, the floating gate 12, the intergate insulator 13 and the control gate 14 configure stacked bodies of electrodes. The stacked bodies and the upper surface of the silicon substrate 10 between the stacked bodies are covered with a thin silicon nitride film (not shown), if required, on which an interlayer insulator 15 such as TEOS (tetraethoxysilane) is formed. The interlayer insulator 15 is buried between the stacked bodies. On the interlayer insulator 15, the bit lines BL are formed selectively.

The NAND-type EEPROM thus configured has the following effect. Namely, the above-described memory cell of the stacked gate structure may have a capacity C1 between the channel and the floating gate and a capacity C2 between the floating gate and the control gate. In this case, the control gate voltage VCG and the floating gate voltage VFG at the time of data write have a relation of VFG=γYVCG as known where γ denotes a coupling ratio, which is represented by γ=C2/(C1+C2).

With the floating gate voltage VFG ensured sufficient, lowering the control gate voltage VCG requires as large an increase in the coupling ratio as possible, The tunnel oxide of the prior art structure has a relative permittivity of about 4, which can not reduce C1 sufficiently. As a result, the coupling ratio γ can not be increased sufficiently and eventually the control gate voltage VCG can not be lowered sufficiently.

Therefore, the flash memory of prior art requires high voltages for write and erase, a longer time for write and erase, larger power consumption, and larger areas of the row decoder and boosters as a problem.

With this regard, in the nonvolatile semiconductor device using the memory cells of the present embodiment including the first cavity layer 11 formed in place of the tunnel oxide, the first cavity layer 11 has a relative permittivity of about 1. Accordingly, the capacity C1 between the floating gate and the channel can be reduced to about ¼ that of the prior art with a relative permittivity of about 4. Thus, the coupling ratio γ can be increased sufficiently and the control gate voltage VCG can be lowered accordingly. This is effective to lower the control gate voltages at the time of data write and erase and reduce the circuit areas of the booster, the row decoder and so forth.

In this embodiment, the first gate insulator layer immediately beneath the floating gate 12 is the cavity layer 11 and accordingly no charge trap is accumulated immediately beneath the floating gate 12. Therefore, the number of rewrite operations cannot be lowered by the reduction in FN tunnel current due to charge traps and thus the number of rewrite operations above 10⁵ can be realized.

In the present embodiment, the first cavity layer 11 has no conduction band and accordingly has a larger barrier height than the tunnel oxide. Therefore, the transmittance of the FN tunnel current may lower and elongate the write and erase time possibly. In this case, however, no charge trap stays in the first gate insulator if it is the first cavity layer 11 and accordingly the thickness of the first gate insulator can be thinned correspondingly (for example, to 80 Å or thinner). As a result, the write and erase time can be reduced.

### Manufacturing Method in First Embodiment

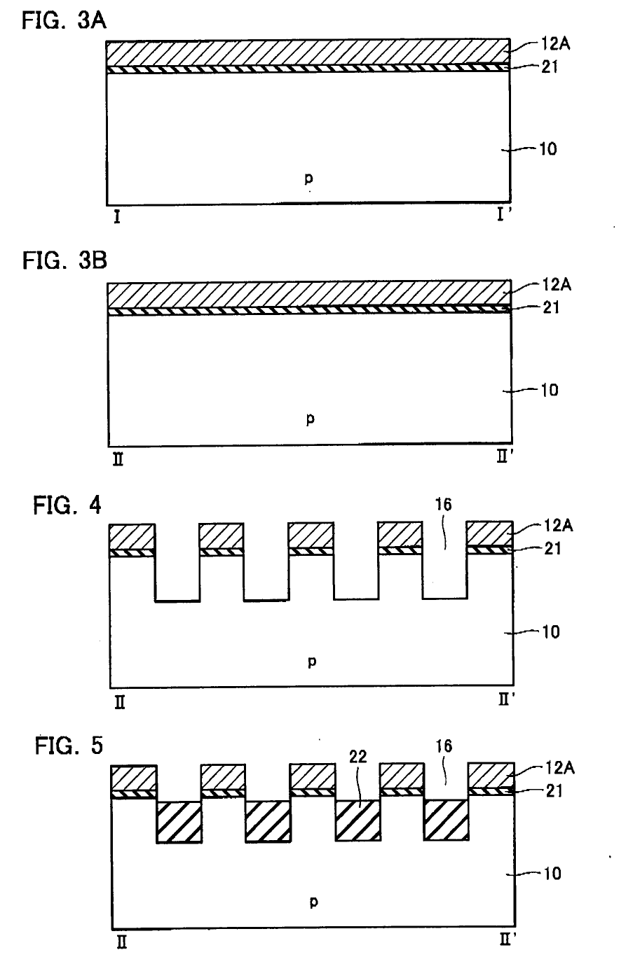

Referring next to FIGS. 3-13, a method of manufacturing the above-described NAND-type EEPROM according to the first embodiment is described.

First, as shown in FIG. 3A (I-I′ section) and FIG. 3B (II-II′ section), a silicon oxide 21 or the first gate insulator layer is formed on the silicon substrate 10 in the memory cell region. A first polysilicon film 12A turned into the floating gate 12 is formed as the first gate layer on the silicon oxide 21. Then, a resist film (not shown) is formed on the first polysilicon film 12A. The resist film is then patterned to selectively remove the first polysilicon film 12A, the silicon oxide 21 and the upper layer of the silicon substrate 10 by anisotropic etching as shown in FIG. 4 (II-II′ section), thereby forming the first isolation trenches 16 extending in the first direction or the row direction.

Subsequently, the resist film is removed and a TEOS film is formed over the entire surface. A process of CMP (Chemical Mechanical Polishing) is applied to planarize the surface of the TEOS film. Further, a wet etching with DHF (Dilute Hydrofluoric acid) or RIE (Reactive Ion Etching) is used to etch back the surface of the TEOS film to form a first insulating film 22 inside the first isolation trenches 16 as shown in FIG. 5 (II-II′ section). The first insulating film 22 is formed such that the upper surface thereof locates lower than the upper surface of the silicon substrate 10.

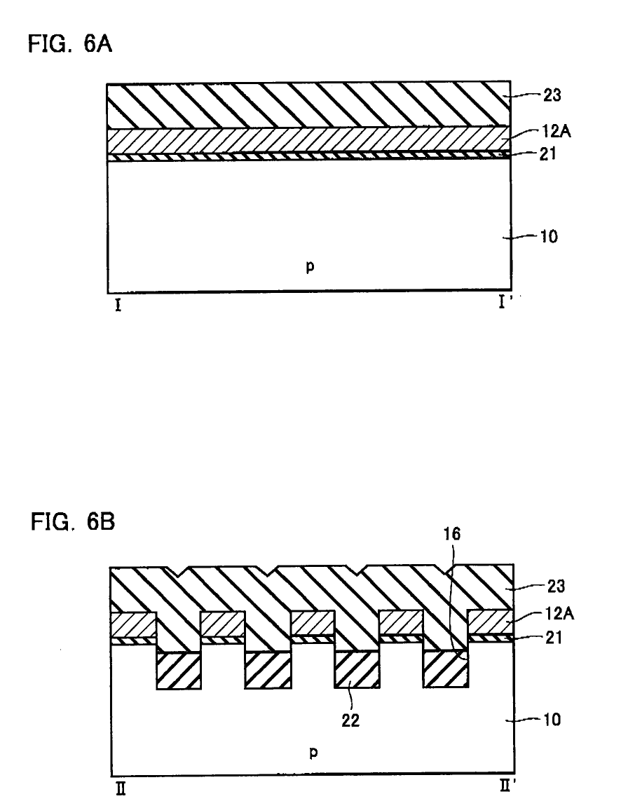

Next, a second insulating film 23 composed of SiN or Al₂O₃ is formed over the entire surface and buried in the trenches on the first insulating film 22 as shown in FIGS. 6A and 6B. The second insulating film 23 may be composed of other material if it has a resistance to a later-described first etchant or hydrofluoric gas (HF-vapor) for removing the silicon oxide 21.

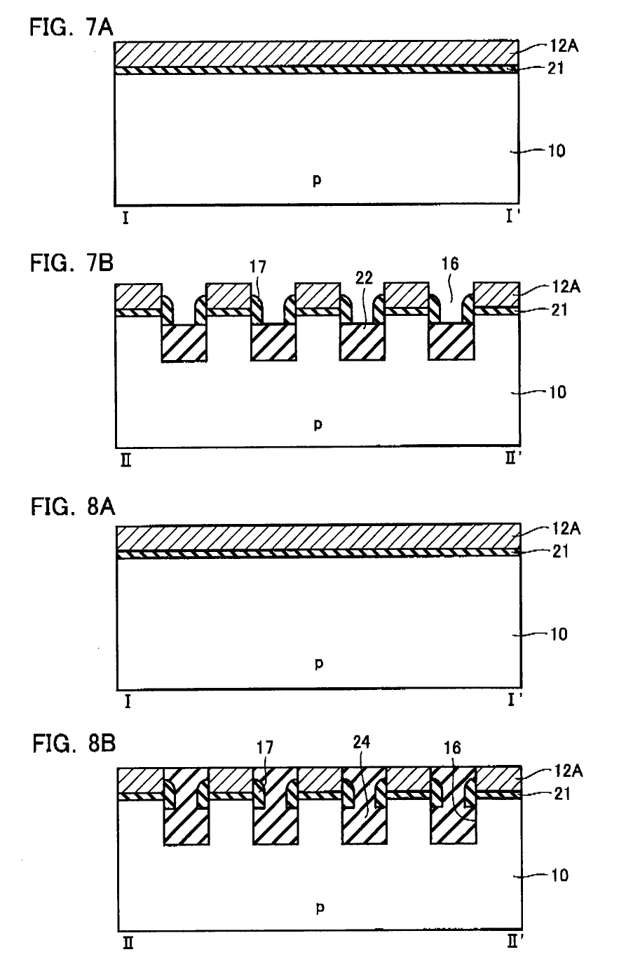

Subsequently, a RIE (Reactive Ion Etching) process with a second etchant different from the first etchant is used to partly remove the second insulating film 23 to form the first support film 17 (first wing) as shown in FIGS. 7A and 7B. The first support film 17 couples the side of the first isolation trench 16 with the side of the polysilicon film 12A.

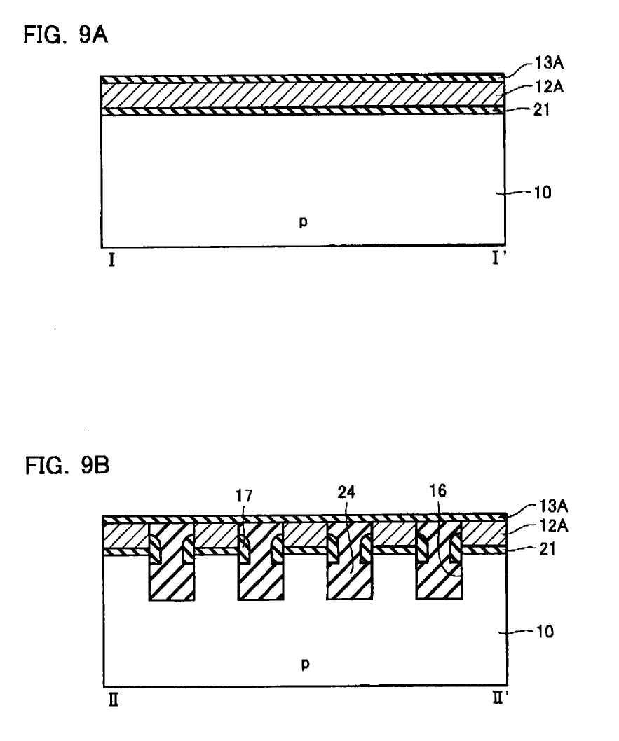

Thereafter, a SiO₂ film is formed over the entire surface to form a third insulating film 24 integrated with the first insulating film 22 as shown in FIGS. 5A and 5B. The surface thereof is then planarized by CMP or the like and, on the upper surface thereof, a second gate insulator layer 13A having HF-resistance, such as an ONO (SiO₂—SiN—SiO₂) film, to be turned into the intergate insulator 13, is formed as shown in FIGS. 9A and 9B.

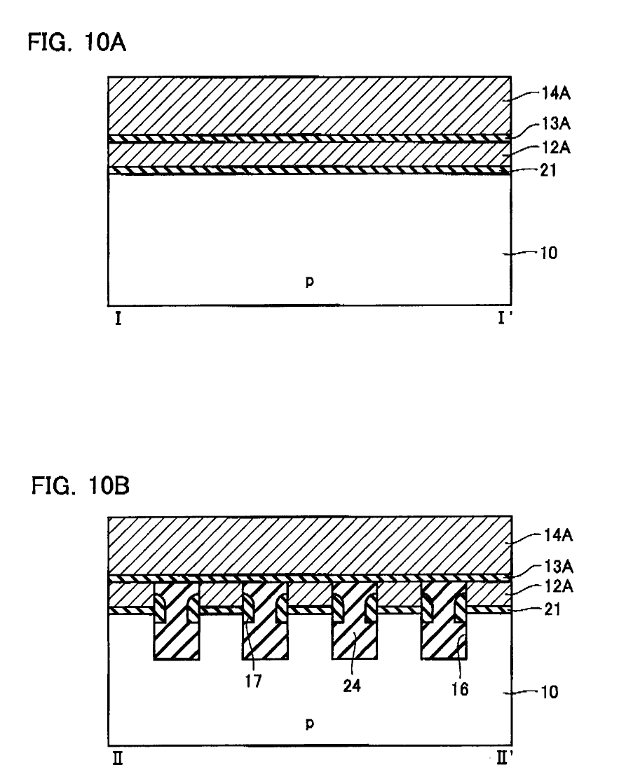

Subsequently, on the second gate insulator layer 13A, a second polysilicon film 14A is formed as the second gate layer to be turned into the control gate 14 as shown in FIGS. 10A and 10B.

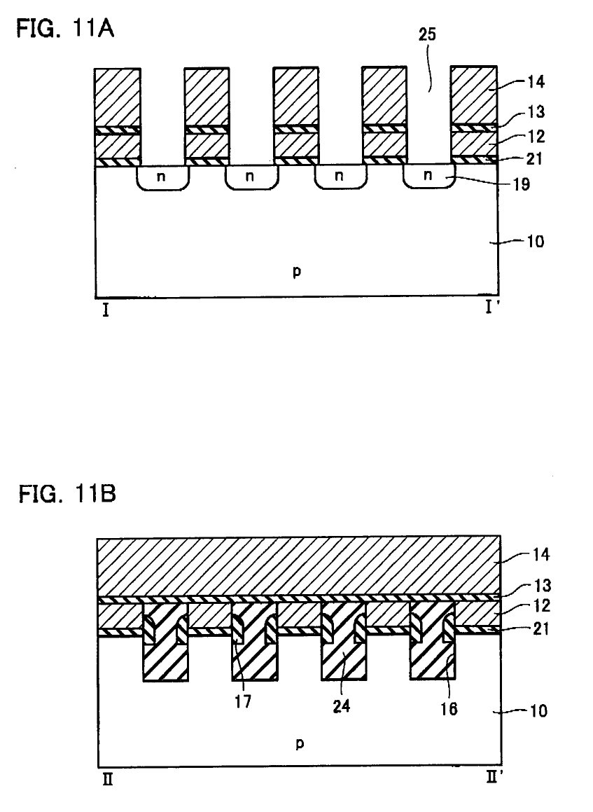

Thereafter, a resist film (not shown) is formed and then patterned, followed by an isotropic etching to selectively remove the second polysilicon film 14A, the second gate insulator layer 13A, the first polysilicon film 12A and the silicon oxide 21 to form second isolation trenches 25. The second isolation trenches extend in a second direction or column direction as shown in FIGS. 11A and 11B, thereby patterning the multi-layered film to form a stacked gate composed of the floating gate 12, the intergate insulator 13 and the control gate 14. In addition, using a mask of the stacked gate, impurity ions are implanted to form the impurity-diffused regions 19.

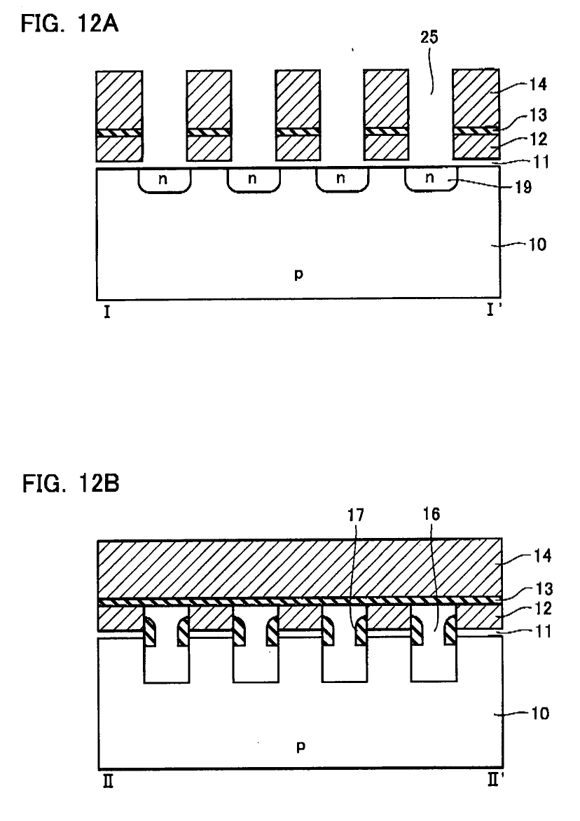

Next, a hydrofluoric gas (HF-vapor) or hydrofluoric acid is used to remove the silicon oxide 21 and the third insulating film 24 to form the first cavity layer 11 between the channel portion in the silicon substrate 10 and the floating gate 12 as shown in FIGS. 12A and 12B.

Finally, the interlayer insulator 15 composed of SiO₂ is formed over the entire surface and then the bit lines BL are formed thereon to complete the structure shown in FIGS. 2A and 2B.

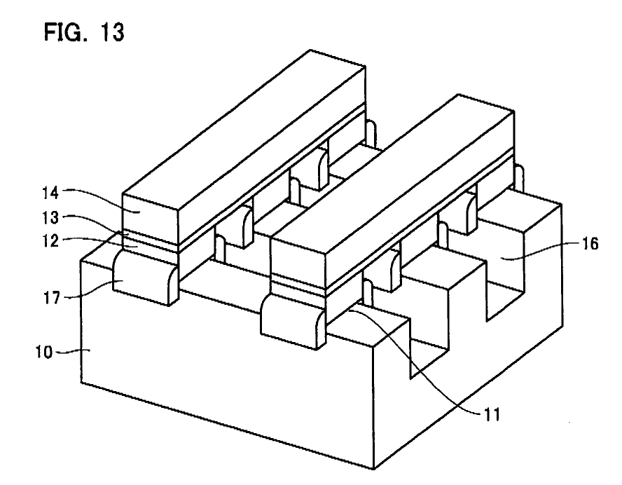

FIG. 13 is a perspective view showing the NAND-type EEPROM according to the present embodiment immediately after the first cavity layer 11 is formed. As obvious from this figure, the silicon oxide 21 is removed from between the silicon substrate 10 and the floating gate 12 to form the first cavity layer 11. In this case, the first support film 17 couples the silicon substrate 10 with the floating gate 12 and accordingly makes the first cavity layer 11 with a certain thickness while preventing the floating gate 12 from dropping.

The first support film 17 is formed locally only on the side of the first isolation trench 16. Accordingly, in the step of removing the silicon oxide 21, the third insulating film 24 buried in the first isolation trench 16 is also removed together. Such the removal of the third insulating film 24 buried in the first isolation trench 16 makes it possible to reduce capacitive coupling between floating gates 12 adjoining via the first isolation trench 16.

### Second Embodiment

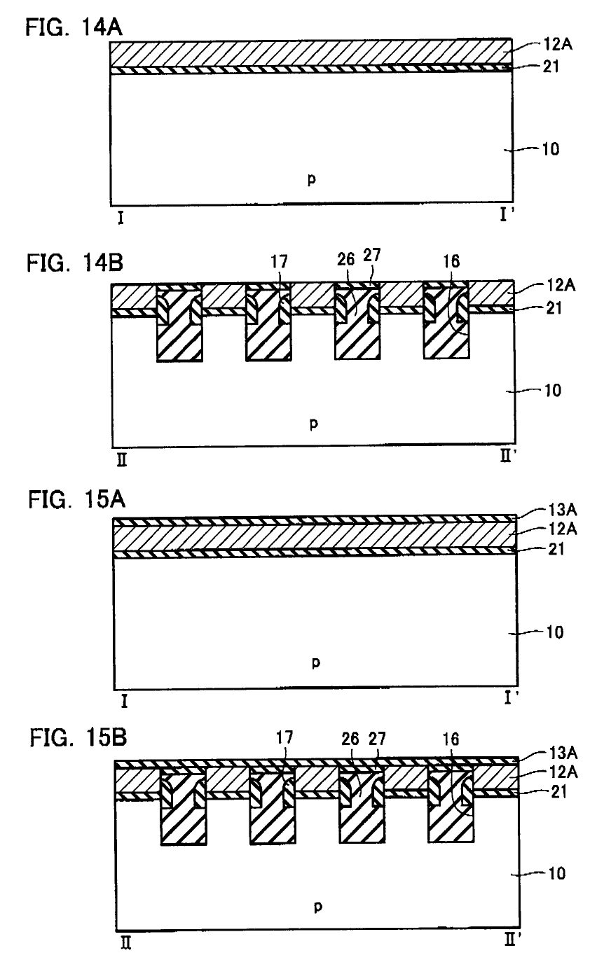

FIGS. 14-22 show process steps of manufacturing a NAND-type EEPROM according to a second embodiment of the present invention.

It is assumed in the preceding embodiment that the intergate insulator 13 has HF-resistance. If an ONO (oxide-nitride-oxide) film or the like having an insufficient etching ratio to SiO₂ is used as the intergate insulator 13, it may be formed as follows.

The steps including and before the step of forming a third insulating film 26 integrated with the first isolation trench 16 are similar to those including and before the step of forming the third insulating film 24 in the first embodiment and therefore omitted from the following detailed description.

As shown in FIGS. 14A and 14B, after formation of the third insulating film 26 integrated with the first isolation trench 16, the upper surface of the third insulating film 26 is planarized by CMP and then slightly etched back using a wet etching or RIE with DHF. Thereafter, a first cover film 27 composed of SiN having HF-resistance is formed over the entire surface and then planarized by CMP to expose the first polysilicon film 12A and leave the first cover film 27 only on the upper surface of the third insulating film 26. If the capacitive coupling between adjoining floating gates presents no problem, then the first cover film 27 may be left over the entire surface.

Next, a second gate insulator layer 13A of SiO₂ or the like turned into the intergate insulator 13 is formed on the upper surfaces of the first polysilicon film 12A and the first cover film 27 as shown in FIGS. 15A and 15B.

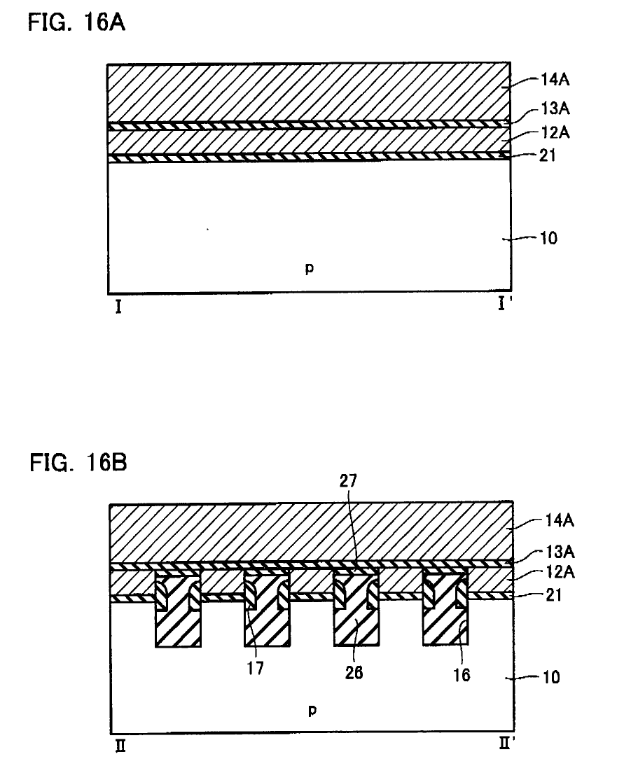

Subsequently, a second polysilicon film 14A turned into the control gate 14 is formed on the first cover film 13A as shown in FIGS. 16A and 16B.

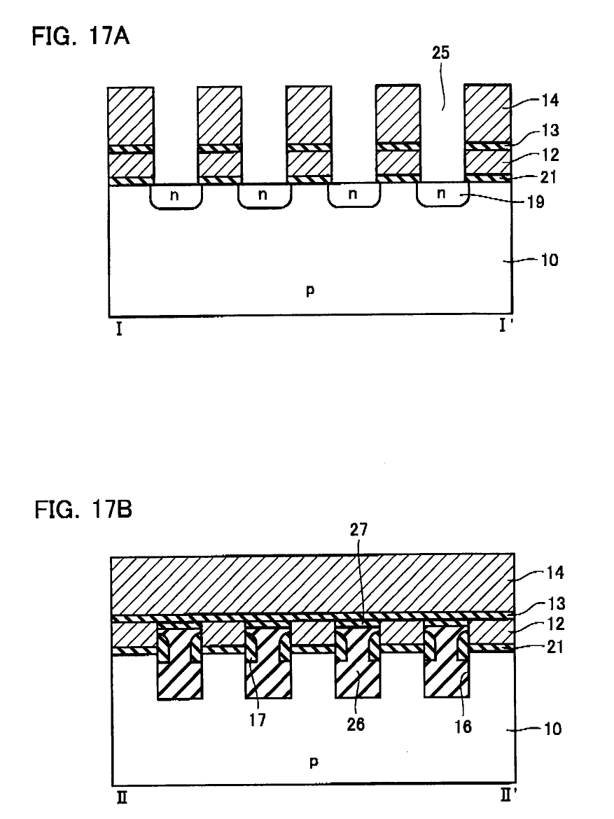

Thereafter, a resist film (not shown) is formed and then patterned, followed by anisotropic etching to selectively remove the second polysilicon film 14A, the second gate insulator layer 13A, the first polysilicon film 12A and the silicon oxide 21 to form second isolation trenches 25. The second isolation trenches 25 extend in the column direction as shown in FIGS. 17A and 17B, thereby patterning the multi-layered film to form a stacked gate composed of the floating gate 12, the intergate insulator 13 and the control gate 14. In addition, using a mask of the stacked gate, impurity ions are implanted to form the impurity-diffused regions 19.

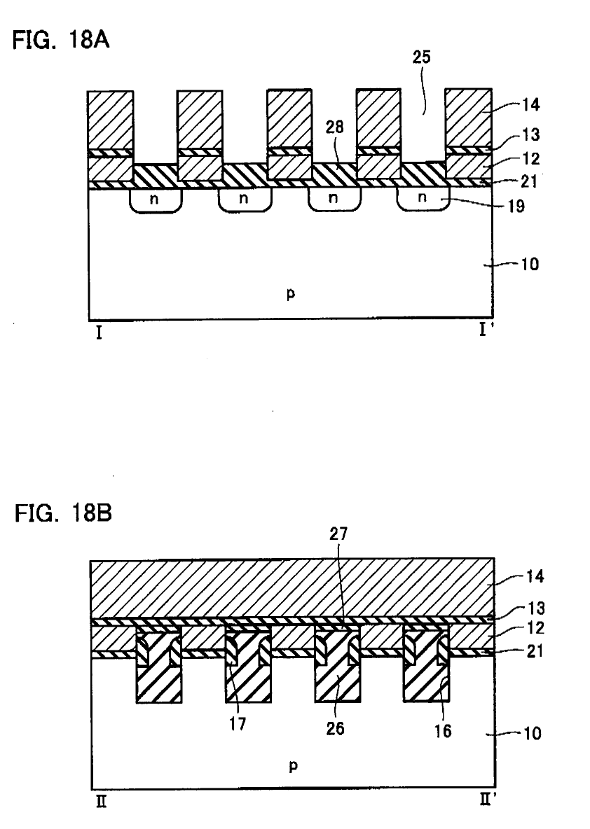

Subsequently, a TEOS film is formed over the entire surface as shown in FIGS. 18A and 18B. The surface of the TEOS film is then planarized by CMP. Further, the surface of the TEOS film is etched back using a wet etching or RIE with DHF to form a fourth insulating film 28 inside the second isolation trenches 25. The fourth insulating film 28 is formed such that the upper surface thereof locates lower than the upper surface of the floating gate 12.

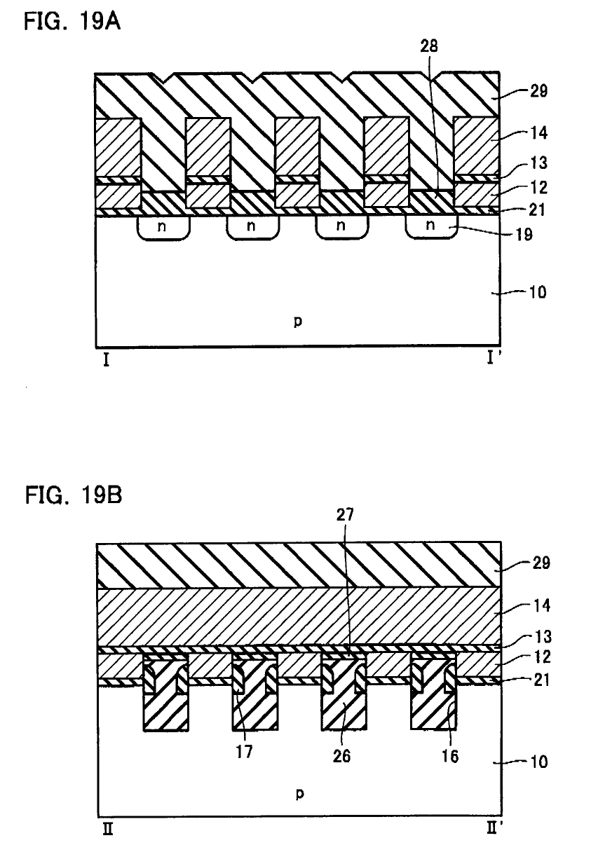

Next, a fifth insulating film 29 composed of SiN or Al₂O₃ is formed over the entire surface and buried in the trenches on the fourth insulating film 28 as shown in FIGS. 19A and 19B. The fifth insulating film 29 may be composed of other material if it has HF-resistance.

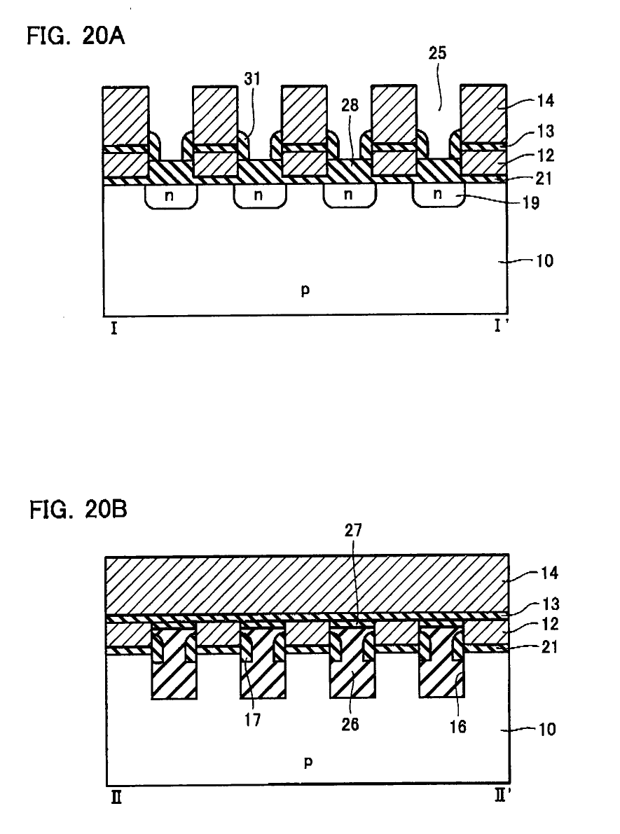

Subsequently, a RIE process or the like is used to partly remove the fifth insulating film 29 to form a second cover film 31 (second wing) as shown in FIGS. 20A and 20B. The second cover film is arranged to couple the sides of the floating gate 12 opposing along the gate length with the sides of the control gate 14 opposing along the gate length and is formed along both the sides to cover the side of the intergate insulator 13.

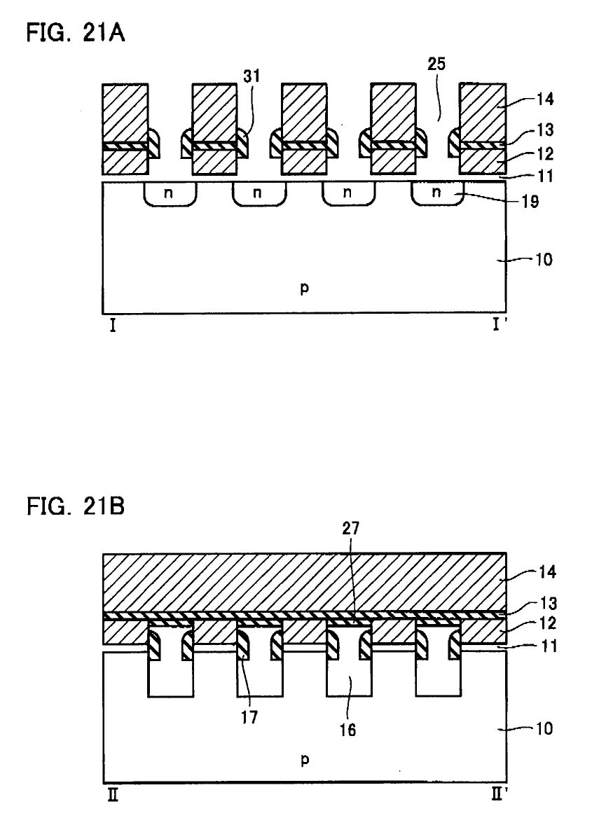

Thereafter, a hydrofluoric gas (HF-vapor) or hydrofluoric acid is used to remove the fourth insulating film 28, the silicon oxide 21 and the third insulating film 26 to form the first cavity layer 11 between the channel portion in the silicon substrate 10 and the floating gate 12 as shown in FIGS. 21A and 21B.

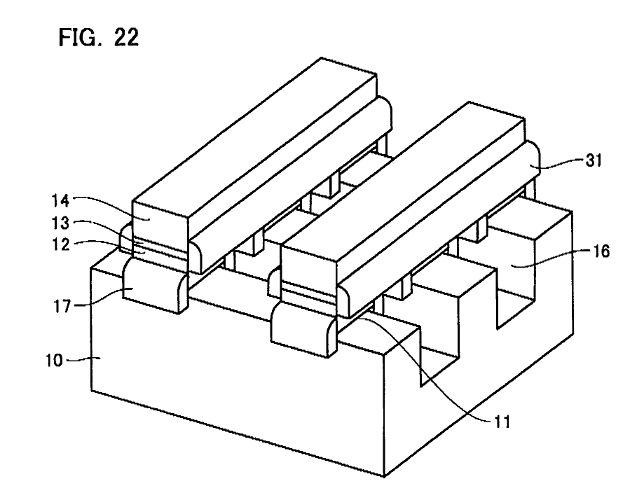

FIG. 22 is a perspective view showing the NAND-type EEPROM according to the present embodiment immediately after the first cavity layer 11 is formed. As obvious from this figure, coupling the silicon substrate 10 with the floating gate 12 by the first support film 17 makes it possible to prevent the floating gate 12 from dropping, like in the preceding embodiment. In the present embodiment, the side of the intergate insulator 13 is covered with the second cover film 13 and the lower surface of the intergate insulator 13 is covered with the first cover film 27. Accordingly, the intergate insulator 13 can be protected from HF on removal of the silicon oxide 21.

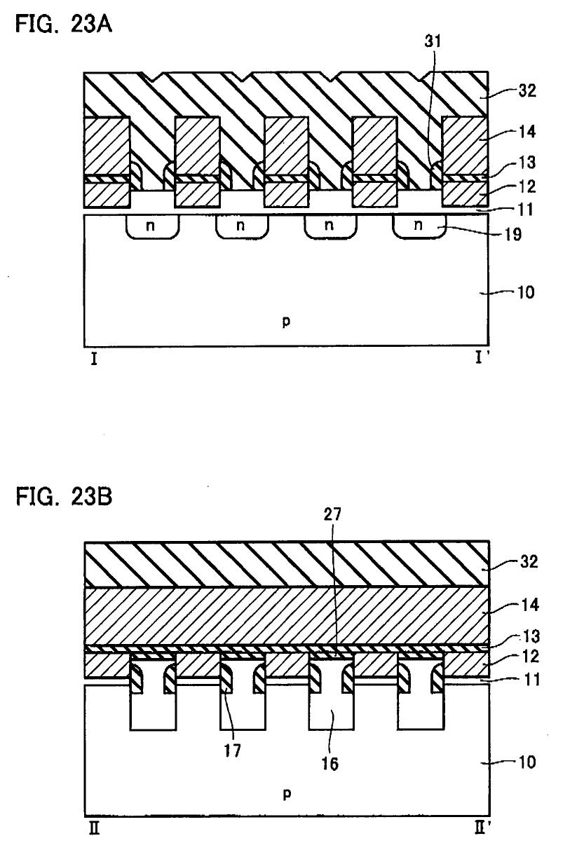

After the above step, an interlayer insulator 32 composed of SiO₂ may be formed over the entire surface to form a space along the channel length of the floating gate 12 as shown in FIGS. 23A and 23B.

### Third Embodiment

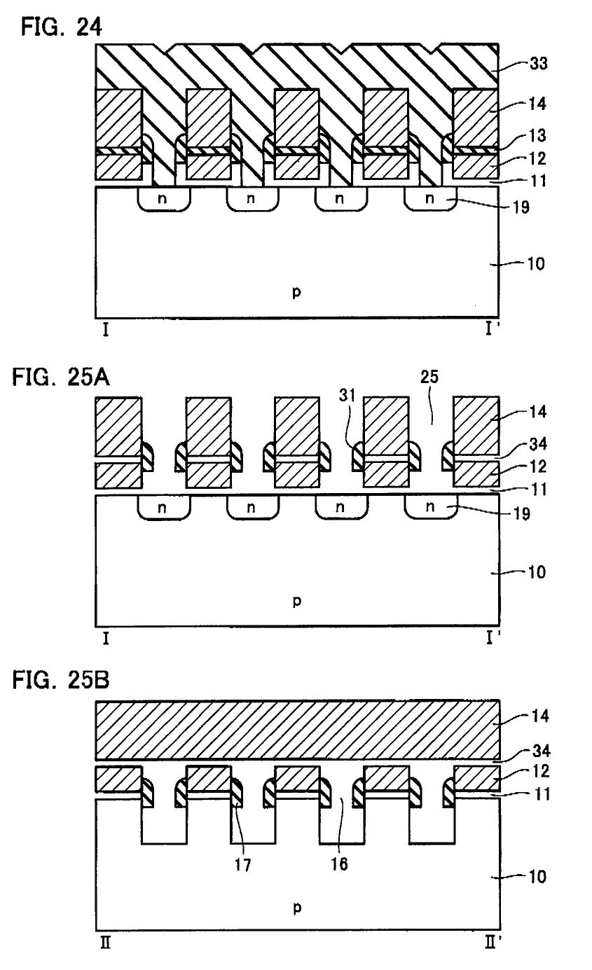

FIG. 24 is a cross-sectional view showing a NAND-type EEPROM according to a third embodiment of the present invention taken along I-I′ line.

In the preceding embodiments, the interlayer insulator 32 has floated bottoms. In the third embodiment, though, an interlayer insulator 33 has bottoms extending in pillar shapes and reaching the silicon substrate 10. With the use of such the structure, the stacked gate structure can be supported surely on the pillars of the interlayer insulator 33.

### Fourth Embodiment

FIGS. 25A and 25B are cross-sectional views showing a NAND-type EEPROM according to a fourth embodiment of the present invention.

In the present embodiment, the first cavity layer 11 formed between the floating gate 12 and the silicon substrate 10 and a second cavity layer 34 is formed between the floating gate 12 and the control gate 14.

This structure can be produced through the similar steps to those in the second embodiment without forming the first cover film 27 of FIG. 14B. In this case, the second cover film 31 serves as a second support film capable of retaining the gap between the floating gate 12 and the control gate 14.

### Other Embodiments

In the above embodiments, the NAND-type EEPROM is exemplified to describe the present invention. The present invention may also be applied to a NOR-type EEPROM, a 3-Tr flash memory and a NANO flash memory.

What is claimed is:

1. A nonvolatile semiconductor memory device, comprising a memory cell array of plural memory cells arranged in matrix, each memory cell including
a first gate insulator layer formed on a semiconductor substrate,
a floating gate formed on the semiconductor substrate with the first gate insulator layer interposed therebetween,
a second gate insulator layer formed on the floating gate, and
a control gate formed on the floating gate with the second gate insulator layer interposed therebetween,
wherein the first gate insulator layer is a first cavity layer.

2. The device according to claim 1, wherein the semiconductor substrate has an isolation trench formed therein extending along a gate length of the floating gate to provide isolation between the memory cells adjoining along the gate width of the floating gate, further comprising
a first support film arranged to couple the side of the isolation trench with the side of the floating gate to keep the first cavity layer with a certain thickness.

3. The device according to claim 1, further comprising a first cover film formed between floating gates in memory cells adjoining along the gate width to cover the lower surface of the second gate insulator layer.

4. The device according to claim 3, further comprising a second cover film arranged so as to couple the sides of the floating gate opposing along the gate length with the sides of the control gate opposing along the gate length, the second cover film formed along both the sides to cover the side of the second gate insulator layer.

5. The device according to claim 1, wherein the second gate insulator is a second cavity layer.

6. The device according to claim 5, further comprising a second support film arranged so as to couple the sides of the floating gate opposing along a gate length of the floating gate and the sides of the control gate opposing along the gate length, the second support film formed along both the sides to keep the second cavity layer.

7. The device according to claim 1, further comprising a cavity between floating gates in memory cells adjoining along the gate width of the floating gate.

8. The device according to claim 1, further comprising an interlayer insulator between control gates in memory cells adjoining along a gate length of the control gate, the interlayer insulator having pillars formed with bottoms reaching the semiconductor substrate.

9. The device according to claim 1, wherein the first cavity layer is kept in a vacuum or filled with an inert gas.

10. A method of manufacturing nonvolatile semiconductor memory devices, comprising:
forming a first gate insulator layer on a semiconductor substrate;
forming a first gate layer turned into a floating gate on the first gate insulator layer;
selectively removing the first gate layer and the first gate insulator layer to form a plurality of first isolation trenches extending in parallel with a first direction in the surface layer of the semiconductor substrate;
forming a first support film to couple the side of the first isolation trench with the side of the first gate layer facing the first isolation trench, the first support film having a resistance to a first etchant;
forming a second gate insulator layer on the first gate layer;
forming a second gate layer turned into a control gate on the second gate insulator layer;
forming a plurality of second isolation trenches extending in parallel with a second direction crossing the first direction, the second isolation trenches reaching from the second gate layer to the surface of the semiconductor substrate; and
forming a first cavity layer between the semiconductor substrate and the first gate layer using the first etchant to remove the first gate insulator layer while leaving the first support film.

11. The method according to claim 10, wherein forming the first support film includes
forming a first insulating film in the first isolation trench such that the upper surface thereof locates lower than the upper surface of the semiconductor substrate,
forming a second insulating film turned into the first support film on the first insulating film, and
selectively removing the second insulating film with a second etchant, leaving a portion to be turned into the first support film.

12. The method according to claim 11, further comprising, after selectively removing the second insulating film:
forming a third insulating film on the first insulating film in the first isolation trench such that the upper surface thereof locates at the same height as the upper surface of the first gate layer; and
forming the second gate insulator layer on the first gate layer and the third insulating film.

13. The method according to claim 12, further comprising forming the first cavity layer using the first etchant to remove the first gate insulator layer, the first insulating layer and the third insulating layer.

14. The method according to claim 13, wherein the second gate insulator layer has a resistance to the first etchant.

15. The method according to claim 11, further comprising, after selectively removing the second insulating film:
forming a third insulating film on the first insulating film in the first isolation trench such that the upper surface thereof locates lower than the upper surface of the first gate layer;
forming a first cover film having a resistance to the first etchant on the third insulating film in the first isolation trench such that the upper surface thereof locates at the same height as the upper surface of the first gate layer; and
forming the second gate insulator layer on the first gate layer and the first cover film.

16. The method according to claim 15, further comprising, before selectively removing the second insulator, forming a second cover film to couple the side of the first gate layer with the side of the second gate layer, the sides forming the second isolation trench, the second cover film having a resistance to the first etchant.

17. The method according to claim 16, further comprising forming the first cavity layer using the first etchant to remove the first gate insulator layer, the first insulating film and the third insulating film.

18. The method according to claim 17, wherein the second gate insulating layer has no resistance to the first etchant.

19. The method according to claim 10, further comprising forming an interlayer insulator in the second isolation trench, the interlayer insulator having the bottom reaching the semiconductor substrate.

20. A method of manufacturing nonvolatile semiconductor memory devices, comprising:
forming a first gate insulator layer on a semiconductor substrate;
forming a first gate layer turned into a floating gate on the first gate insulator layer;
selectively removing the first gate layer and the first gate insulator layer to form a plurality of first isolation trenches extending in parallel with a first direction in the surface layer of the semiconductor substrate;
forming a first support film to couple the side of the first isolation trench with the side of the first gate layer facing the first isolation trench, the first support film having a resistance to a first etchant;
forming a second gate insulator layer on the first gate layer;
forming a second gate layer turned into a control gate on the second gate insulator layer;
forming a plurality of second isolation trenches extending in parallel with a second direction crossing the first direction, the second isolation trenches reaching from the second gate layer to the surface of the semiconductor substrate;
forming a second support film to couple the side of the first gate layer with the side of the second gate layer, the sides forming the second isolation trench, the second support film having a resistance to the first etchant; and
forming the first cavity layer between the semiconductor substrate and the first gate layer and forming the second cavity layer between the first gate layer and the second gate layer using the first etchant to remove the first and second gate insulator layers while leaving the first and second support films.
